(19) United States
(12) Patent Application Publication
(10) Pub. No.: US 2026/0182320 A1
(43) Pub. Date: Jun. 25, 2026

(54) BONDING STRUCTURE AND MANUFACTURING METHOD THEREOF

(71) Applicant: Doctech limited, Taichung (TW)

(72) Inventors: SHIEN-PING FENG, Taichung (TW); YU-TING HUANG, Taichung (TW); SHENG-JYE CHERNG, Taichung (TW); CHIH-CHUN CHUNG, Taichung (TW)

(21) Appl. No.: 19/124,990

(22) PCT Filed: Dec. 27, 2022
(86) PCT No.: PCT/CN2022/142269

§ 371 Date: Apr. 28, 2025

(30) Foreign Application Priority Data
Oct. 26, 2022 (CN) 202211320444.4

(51) Int. Cl. H10W 10/10; H10W 10/17; H10W 72/20; H10W 90/00

(52) U.S. Cl. CPC H10W 10/181; H10W 10/17; H10W 72/20; H10W 72/251; H10W 90/722

(57) ABSTRACT

A bonding structure is provided. The bonding structure includes a first structure portion and a second structure portion. The first structure portion includes a first base portion and a first connection portion disposed on a side of the first base portion, where the first base portion and the first connection portion have a same conductive material, and activity of the first connection portion is greater than activity of the first base portion. The second structure portion includes a second base portion and a second connection portion disposed on a side of the second base portion, where the second base portion and the second connection portion have a same conductive material, and activity of the second connection portion is greater than activity of the second base portion. The first and second structure portion are connected to each other by docking the first connection portion with the second connection portion.

### TECHNICAL FIELD

The present invention relates to a bonding structure and a manufacturing method thereof, and in particular, to a bonding structure and a manufacturing method thereof for an interconnection of a semiconductor chip or an electronic structure.

### BACKGROUND

In the related art, in a mental docking structure such as copper-copper bonding, metals with a relatively stable property generally need to be selected and bonded, so as to ensure stability of an electrical property after connection. However, in this method, a relatively high binding force is required, the metals need to be assembled in an ultra-vacuum environment, an inert environment, or a reduction environment, with a temperature much higher than a reflow temperature (greater than 300° C.), expensive and complex chemical mechanical polishing (CMP) is used for a seamless bonding step, and a relatively long annealing/bonding process cycle is required. In copper-copper direct bonding, after the chemical mechanical polishing (CMP) step, a dielectric region around a copper electrode is recessed to remove a copper oxide layer and improve flatness of a surface of the copper electrode. In this method, a distinct bonding interface is easily formed, and it is relatively difficult to fill a narrow gap/hole between dielectric layers in the bonding structure.

On the other hand, in a metal docking structure in the related art, in order to increase a bonding effect, docking portions are aligned as much as possible to increase a contact area. In other words, an alignment precision requirement in the process needs to be relatively high to maintain a yield, increasing manufacturing costs. In conclusion, existing metal docking structures have room for improvement.

### SUMMARY

An objective of the present invention is to provide a bonding structure with relatively few defects or holes generated during bonding.

Another objective of the present invention is to provide a manufacturing method of a bonding structure, so as to reduce manufacturing costs and reduce defects or holes generated during bonding.

In the present invention, the bonding structure includes a first structure portion and a second structure portion. The first structure portion includes a first base portion and a first connection portion disposed on a side of the first base portion, where the first base portion and the first connection portion have a same conductive material, and activity of the first connection portion is greater than activity of the first base portion. The second structure portion includes a second base portion and a second connection portion disposed on a side of the second base portion, where the second base portion and the second connection portion have a same conductive material, and activity of the second connection portion is greater than activity of the second base portion. The first structure portion and the second structure portion are connected to each other by docking the other side of the first connection portion with respect to the first base portion with the other side of the second connection portion with respect to the second base portion.

In an embodiment, the first base portion and the second base portion are nano-twinned copper layers.

In an embodiment, the first connection portion and the second connection portion have a self-annealing (self-annealing) property.

In an embodiment, the first connection portion and the second connection portion have a characteristic peak in a (111) direction.

In an embodiment, no obvious interface is formed at a position at which the first connection portion and the second connection portion are docked.

In an embodiment, the first base portion, the first connection portion, the second base portion, and the second connection portion are disposed along a Y axis, and the first connection portion and the second connection portion are aligned in a direction of the Y axis.

In an embodiment, the first base portion, the first connection portion, the second base portion, and the second connection portion are disposed along a Y axis, and the first connection portion and the second connection portion are partially misaligned in a direction of the Y axis.

In an embodiment, the first base portion, the first connection portion, the second base portion, and the second connection portion are disposed along a Y axis, and an area of the second connection portion in a direction perpendicular to the Y axis is smaller than an area of the first connection portion in the direction perpendicular to the Y axis.

In an embodiment, the first structure portion further includes a first substrate and a first isolation layer. The first base portion is disposed on one side of the first substrate, and the first connection portion is disposed on the other side of the first base portion with respect to the first substrate. The first isolation layer is disposed on the same side of the first substrate as the first base portion, and surrounds the first base portion and the first connection portion. The second structure portion further includes a second substrate and a second isolation layer. The second base portion is disposed on one side of the second substrate, and the second connection portion is disposed on the other side of the second base portion with respect to the second substrate. The second isolation layer is disposed on the same side of the second substrate as the second base portion, and surrounds the second base portion and the second connection portion.

In an embodiment, the first isolation layer and the second isolation layer are made of an insulating material.

The manufacturing method of a bonding structure in the present invention includes the following steps: providing the foregoing first structure portion; providing the foregoing second structure portion, where the provided first structure portion includes: a first substrate; a first base portion, disposed on a side of the first substrate; a first connection portion, disposed on the other side of the first base portion with respect to the first substrate, where the first base portion and the first connection portion have a same conductive material, and activity of the first connection portion is greater than activity of the first base portion; and a first isolation layer, disposed on the same side of the first substrate as the first base portion, and surrounding the first base portion and the first connection portion; and the provided second structure portion includes: a second substrate; a second base portion, disposed on a side of the second substrate; a second connection portion, disposed on a side of the second base portion, where the second base portion and the second connection portion have a same conductive material, and activity of the second connection portion is greater than activity of the second base portion; and a second isolation layer, disposed on the same side of the second substrate as the second base portion, and surrounding the second base portion and the second connection portion; and docking the other side of the first connection portion in the first structure portion with respect to the first base portion with the other side of the second connection portion in the second structure portion with respect to the second base portion to connect the first structure portion and the second structure portion.

In an embodiment, the step of providing a first structure portion includes: providing a first substrate; disposing a first isolation layer on a side of the first substrate; forming multiple first through holes in the first isolation layer; forming a first base portion on the first substrate in the multiple first through holes; and forming a first connection portion on the first base portion.

In an embodiment, the step of docking the other side of the first connection portion with respect to the first base portion with the other side of the second connection portion with respect to the second base portion includes: bringing the other side of the first connection portion with respect to the first base portion into contact with the other side of the second connection portion with respect to the second base portion; and activating the other side of the first connection portion with respect to the first base portion and the other side of the second connection portion with respect to the second base portion.

In an embodiment, the first base portion, the first connection portion, the second base portion, and the second connection portion are disposed along a Y axis, where the step of bringing the other side of the first connection portion with respect to the first base portion into contact with the other side of the second connection portion with respect to the second base portion includes: aligning the first connection portion and the second connection portion in a direction of the Y axis.

In an embodiment, the first base portion, the first connection portion, the second base portion, and the second connection portion are disposed along a Y axis, where the step of bringing the other side of the first connection portion with respect to the first base portion into contact with the other side of the second connection portion with respect to the second base portion includes: partially misaligning the first connection portion and the second connection portion in a direction of the Y axis.

In an embodiment, the step of activating the other side of the first connection portion with respect to the first base portion and the other side of the second connection portion with respect to the second base portion includes: increasing a temperature of the first structure portion and a temperature of the second structure portion.

In an embodiment, the first base portion and the second base portion are made of nano-twinned copper.

In an embodiment, the first connection portion and the second connection portion have a self-annealing property.

In an embodiment, the first connection portion and the second connection portion have a characteristic peak in a (111) direction.

In an embodiment, the first isolation layer and the second isolation layer are made of an insulating material.

### BRIEF DESCRIPTION OF THE DRAWINGS

FIG. 1 is a schematic diagram of an embodiment of a bonding structure according to the present invention;

FIG. 2A is a surface scanning electron microscope diagram of a nano-twinned copper layer;

FIG. 2B is a focused ion beam cross-sectional view of a nano-twined copper layer;

FIG. 3A and FIG. 3B are schematic diagrams of different embodiments of a bonding structure according to the present invention;

FIG. 4 is a schematic flowchart of an embodiment of a manufacturing method of a bonding structure according to the present invention;

FIG. 5A to FIG. 5E are schematic diagrams of embodiments of manufacturing a first structure portion according to the present invention; and

FIG. 6A to FIG. 6D are schematic diagrams of different embodiments of manufacturing a first structure portion according to the present disclosure.

### DESCRIPTION OF MAIN ELEMENT SYMBOLS

100 First structure portion
110 First base portion
110a Side
110b Side
120 First connection portion
120a Side
120c Side
130 First substrate
130b Side
140 First isolation layer
140a First through hole
200 Second structure portion
210 Second base portion
210a Side
210b Side
220 Second connection portion
220a Side
220c Side
230 Second substrate
230b Side
240 Second isolation layer
710 Nano-twinned copper grain
720 Irregular crystal phase region
800 Bonding structure
1000, 1100, 1200, 1300, 1400, 1500, 2000, 2100, 2200, 2300, 2400, 2500, 3000 Steps
Y Y axis

### DETAILED DESCRIPTION

The following describes the embodiments of the bonding structure disclosed in the present invention through specific embodiments and accompanying drawings. A person skilled in the art can understand advantages and effects of the present invention according to content disclosed in this specification. However, the content disclosed in the following is not intended to limit a protection scope of the present invention. A person skilled in the art can implement the present invention by using different embodiments based on different opinions and applications without departing from the concept and spirit of the present invention. In the accompanying drawings, the thicknesses of layers, films, panels, regions, and the like are enlarged for clarity. Throughout the specification, same reference numerals indicate same elements. It should be understood that when an element such as a layer, film, region, or substrate is referred to as being “on” or “connected to” another element, the element may be directly on or connected to the another element, or an intermediate element may exist. In contrast, when an element is referred to as being “directly on” or “directly connected to” another element, no intermediate element exists. As used herein, “connection” may refer to a physical and/or electrical connection. In addition, “electrical connection” or “coupling” may mean another element exists between two elements.

It should be understood that although terms such as “first”, “second”, “third”, and the like in this specification may be used for describing various elements, components, regions, layers, and/or portions in this specification, the elements, components, regions, layers, and/or portions should not be limited by these terms. The terms are only used to distinguish one element, component, region, layer, or portion from another element, component, region, layer, or portion. Therefore, the first “element”, “component”, “region”, “layer”, or “portion” described below may be referred to as a second element, component, region, layer, or portion without departing from the teachings of the present invention.

In addition, relative terms such as “below”, “bottom”, “above”, or “top” are used in this specification to describe a relationship between one element and another element, as shown in the figures. It should be understood that such relative terms are intended to include different orientations of an apparatus in addition to the orientation shown in the figures. For example, if the apparatus in a figure is turned over, an element described as being “below” with respect to another element is to be “above” with respect to the another element. Therefore, the exemplary term “below” may include both the below and above orientations depending on the spatial orientation in the figures. Similarly, if the apparatus in a figure is turned over, an element described as being “below” or “below” with respect to another element is to be “above” with respect to the another element. Therefore, the exemplary term “above” or “below” may include both the above and below orientations.

As used herein, “about”, “approximately”, or “substantially” includes a stated value and means within an acceptable range of deviation for the particular value as determined by a person of ordinary skill in the art, considering the measurement in question and the error associated with measurement of the particular quantity (that is, a limitation of a measurement system). For example, “about” may mean within one or more standard deviations, or within ±30%, ±20%, ±10%, ±5% of the stated value. Further, as used herein, “about”, “approximately”, or “substantially” may depend on an optical property, etch property, or another property to select a more acceptable deviation range or standard deviation without one standard deviation for all properties.

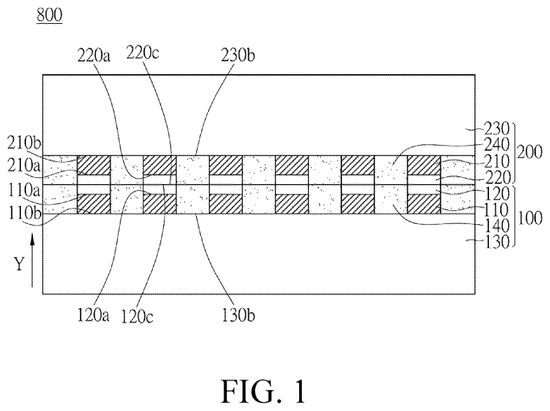

As shown in an embodiment of FIG. 1, a bonding structure 800 in the present invention includes a first structure portion 100 and a second structure portion 200. The first structure portion 100 includes a first base portion 110 and a first connection portion 120 disposed on a side 110a of the first base portion 110, where the first base portion 110 and the first connection portion 120 have a same conductive material, and activity of the first connection portion 120 is greater than activity of the first base portion 110. The second structure portion 200 includes a second base portion 210 and a second connection portion 220 disposed on a side 210a of the second base portion 210, where the second base portion 210 and the second connection portion 220 have a same conductive material, and activity of the second connection portion 220 is greater than activity of the second base portion 210. The first structure portion 100 and the second structure portion 200 are connected to each other by docking the other side 120c of the first connection portion 120 with respect to the first base portion 110 with the other side 220c of the second connection portion 220 with respect to the second base portion 210. The same conductive material is, for example, metals having a same element but different crystal phases or crystal structures. For example, the first structure portion and the first base portion may have different atomic structures, crystal structures, material activities, or the like, thus achieving a relatively good bonding effect through different selections and combinations.

Further, the first structure portion 100 further includes a first substrate 130 and a first isolation layer 140. The first base portion 110 is disposed on one side 130b of the first substrate 130, and the first connection portion 120 is disposed on the other side 110a of the first base portion 110 with respect to the first substrate 130. The first isolation layer 140 is disposed on the same side 130b of the first substrate 130 as the first base portion 110, and surrounds the first base portion 110 and the first connection portion 120. The second structure portion 200 further includes a second substrate 230 and a second isolation layer 240. The second base portion 210 is disposed on one side 230b of the second substrate 230, and the second connection portion 220 is disposed on the other side 210a of the second base portion 210 with respect to the second substrate 230. The second isolation layer 240 is disposed on the same side 230b of the second substrate 230 as the second base portion 210, and surrounds the second base portion 210 and the second connection portion 220. The first substrate 130 and the second substrate 230 may be silicon substrates. The first isolation layer 140 and the second isolation layer 240 may be dielectric materials such as silicon oxide, polymers, or any suitable insulation material. In an embodiment, the bonding structure 800 in the present invention is configured for an integrated circuit package, metal docking on a related polymer carrier, or a metal contact with a requirement for metal bonding. The first base portion 110, the first connection portion 120, the second base portion 210, the second connection portion 220, and the like are interconnections in a metal conductor, such as a copper pillar, a copper wire, or the like in the integrated circuit package.

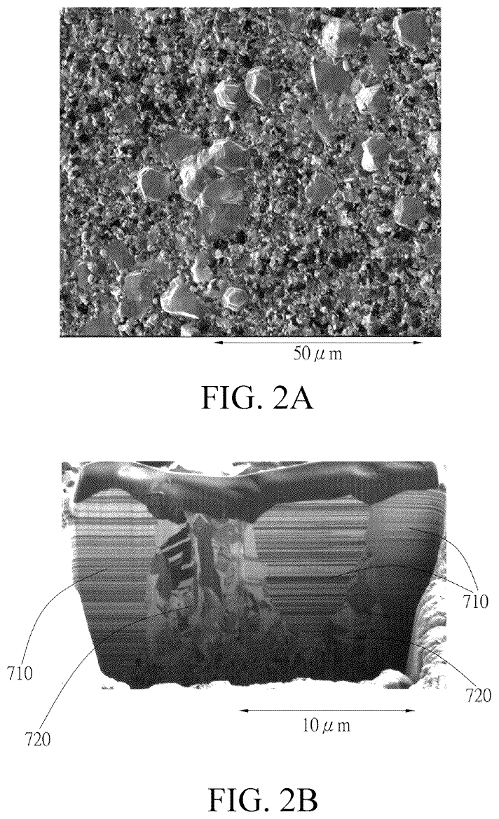

More specifically, in an embodiment, the first base portion 110 and the second base portion 210 are nano-twinned copper layers. FIG. 2A and FIG. 2B are, respectively, a surface scanning electron microscope (SEM) diagram and a focused ion beam (FIB) cross-sectional view of a nano-twinned copper layer. As shown in FIG. 2A and FIG. 2B, the nano-twinned copper includes a plurality of nano-twinned copper grains 710, at least some of the plurality of nano-twinned copper grains 710 have a pillar cap shape that is wide at the top and narrow at the bottom, and an irregular crystal phase region 720 exists between some adjacent nano-twinned copper grins of the plurality of nano-twinned copper grains 710. Specifically, the plurality of nano-twinned copper grains 710 having the pillar cap shape that is wide at the top and narrow at the bottom are configured in a structure similar to a truss structure (truss structure), for example, a Warren truss structure. In other words, some of the plurality of nano-twinned copper grains 710 have a cross-sectional shape similar to an inverted triangle, and the irregular crystal phase region 720 is clamped between adjacent nano-twinned copper grains 710. In an embodiment, the irregular crystal phase region 720 is doped with nano-twinned copper, polycrystalline copper, or a combination thereof with different angle inclinations. The nano-twinned copper grain 710 may have a characteristic peak in a (111) direction, that is, have a (111) crystal axis. Microscopic grain structures of the plurality of nano-twinned copper grains 710 of the nano-twinned copper layer and the irregular crystal phase region 720 therebetween do not change significantly after a considerable time (for example, but not limited to, 20 days), indicating high structural stability. In a different embodiment, the first base portion 110 and the second base portion 210 may be other structures with high stability, and the two are not limited to being the same.

In addition, in an embodiment, the first connection portion 120 and the second connection portion 220 have a self-annealing property. More specifically, in an embodiment, the first connection portion 120 and the second connection portion 220 have a characteristic peak in a (111) direction, which may cause recrystallization (recrystallization) at a relatively high temperature such as a room temperature, thereby changing a microstructure/crystal feature of the first connection portion 120 and the second connection portion 220. Therefore, compared with the first base portion 110 and the second base portion 210, the first connection portion 120 and the second connection portion 220 have a relatively unstable property at a relatively high temperature. From a different perspective, the activity of the first connection portion 110 is greater than the activity of the first base portion 120, and the activity of the second connection portion 220 is greater than the activity of the second base portion 210. Through an activity difference between a base portion and a connection portion, the connection portion with relatively large activity may help bonding and joining between interfaces, thereby effectively strengthening an adhesion force and a joining force of interface joining. With an originally highly stable base portion, after upper layers are docked by using a relatively active connection layer, a stable recrystallization connection layer is formed, and the originally relatively stable base portion is also not affected by temperature raising and pressure during the docking process, maintaining a good property of the base portion. In a different embodiment, the first connection portion 120 and the second connection portion 220 may have a property other than self-annealing, so that the activity of the first connection portion 120 and the activity of the second connection portion 220 are respectively greater than the activity of the first base portion 110 and the activity of the second base portion 210, and a factor distinguishing the activity is not limited to a temperature.

Further, in the related art, in a mental docking structure such as copper-copper bonding, a distinct bonding interface is easily formed, and it is difficult to fill a narrow gap/hole between dielectric layers in the bonding structure. Correspondingly, the bonding structure 800 in the present invention has a relatively good bonding property during docking because the first connection portion 120 and the second connection portion 220 have relatively great activity. Therefore, no distinct bonding interface exists, and there are few defects or holes. In some embodiments, a relatively active connection portion may provide a function similar to an interface bonding agent. With the help of a slight increase in temperature, the connection portion may have a property similar to a slightly molten or activated surface, thereby providing kinetic energy for movement of atoms in a surface material, and providing interface viscosity and further increasing an interface adhesion force. Because the first base portion 110 and the second base portion 210 have high structural stability, stability of properties such as an electrical property after connection can still be ensured. From a different perspective, the bonding structure 800 in the present invention may be considered as a hybrid bonding (Hybrid Bonding) structure of a stable metal/an active metal/an active metal/a stable metal.

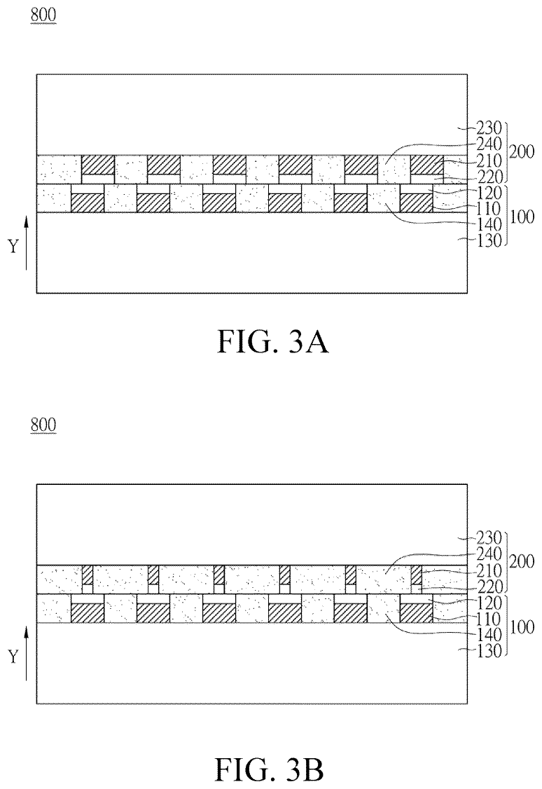

In addition, in the embodiment shown in FIG. 1, the first base portion 110, the first connection portion 120, the second base portion 210, and the second connection portion 220 are disposed along a Y axis, and the first connection portion 120 and the second connection portion 220 are aligned in a direction of the Y axis. However, in a different embodiment, based on a design or process requirement, the first connection portion 120 and the second connection portion 220 may not be aligned in the direction of the Y axis. More specifically, in an embodiment shown in FIG. 3A, the first connection portion 120 and the second connection portion 220 are partially misaligned in a direction of the Y axis. In an embodiment shown in FIG. 3B, an area of the second connection portion 220 in a direction perpendicular to the Y axis is smaller than an area of the first connection portion 120 in the direction perpendicular to the Y axis. Further, in a metal docking structure such as copper-copper docking in the related art, in order to increase a bonding effect, docking portions are aligned as much as possible to increase a contact area. Correspondingly, the bonding structure 800 in the present invention has a relatively good bonding property during docking because the first connection portion 120 and the second connection portion 220 have relatively great activity, and can still obtain an acceptable bonding effect in a misalignment state, which is more flexible in terms of design and manufacturing. From a different perspective, the bonding structure 800 in the present invention has a relatively low requirement on an alignment degree of the docking portions, that is, a good bonding effect is still obtained when a considerable degree (for example, 20% or less) of misalignment exists between the first connection portion 120 and the second connection portion 220.

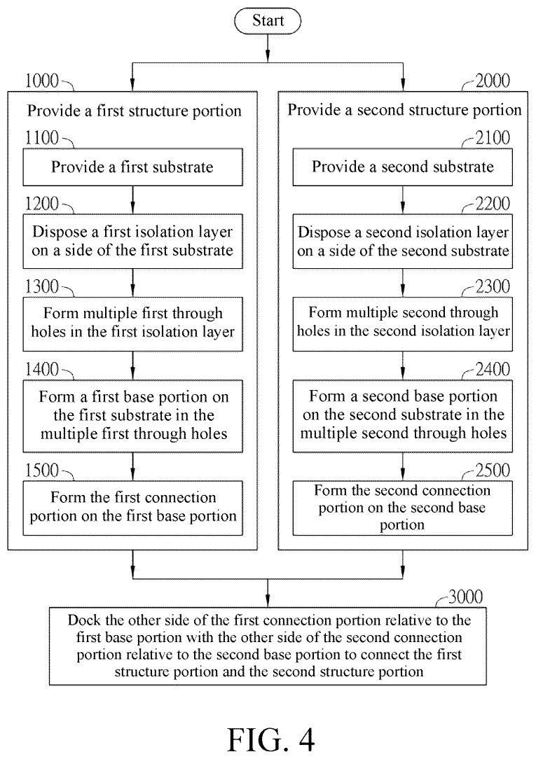

In a flowchart of an embodiment shown in FIG. 4, a structure manufacturing method in the present invention includes, for example, the following steps:

Step 1000: Provide the foregoing first structure portion. Further, for example, the first structure portion 100 shown in FIG. 1, FIG. 3A, and FIG. 3B is provided.

Step 2000: Provide the foregoing second structure portion. Further, for example, the second structure portion 200 shown in FIG. 1, FIG. 3A, and FIG. 3B is provided.

Step 3000: Dock the other side of the first connection portion in the first structure portion with respect to the first base portion with the other side of the second connection portion in the second structure portion with respect to the second base portion to connect the first structure portion and the second structure portion. Further, as shown in FIG. 1, FIG. 3A, and FIG. 3B, the first structure portion 100 and the second structure portion 200 are connected to each other by docking the other side 120c of the first connection portion 120 with respect to the first base portion 110 with the other side 220c of the second connection portion 220 with respect to the second base portion 210. In an embodiment, in Step 3000, the first connection portion 120 and the second connection portion 220 may be aligned in a direction of the Y axis as shown in FIG. 1. In another embodiment, based on a design or manufacturing requirement, in Step 3000, the first connection portion 120 and the second connection portion 220 may be partially misaligned in a direction of the Y axis as shown in FIG. 3A.

More specifically, Step 1000 includes, for example, the following steps:

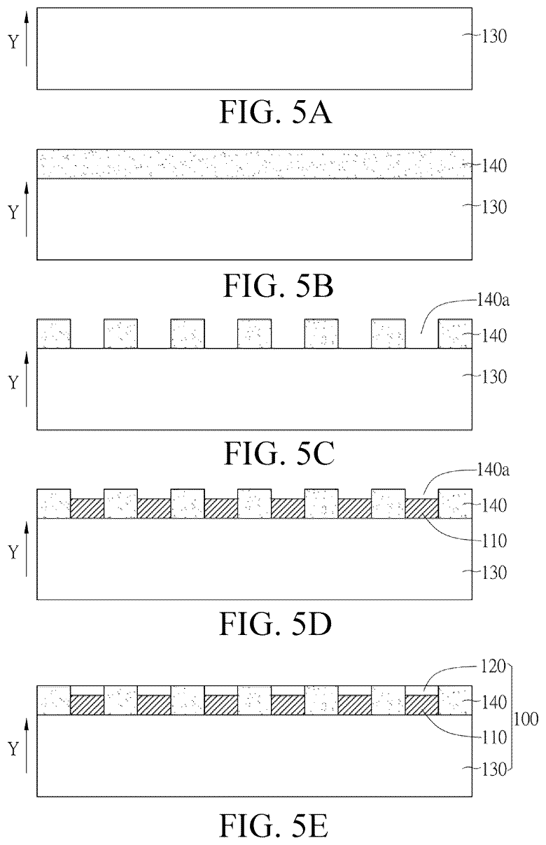

Step 1100: Provide a first substrate. Further, for example, the first substrate 130 shown in FIG. 5A is provided. The first substrate 130 may be a silicon wafer or a part thereof, or made of another material.

Step 1200: Dispose a first isolation layer on a side of the first substrate. Further, as shown in an embodiment shown in FIG. 5B, for example, the first isolation layer 140 is formed on a side of the first substrate 130 in a printing or deposition manner. The printing manner may be, for example, screen printing. The deposition manner may be physical vapor deposition (PVD) such as a sputtering process, and/or may be chemical vapor deposition (CVD).

Step 1300: Form multiple first through holes in the first isolation layer. Further, in an embodiment shown in FIG. 5C, the first isolation layer 140 is processed by, for example, photolithography, to form the multiple first through holes 140a.

Step 1400: Form a first base portion on the first substrate in the multiple first through holes. Further, in an embodiment shown in FIG. 5D, for example, the first base portion 110 is formed on the first substrate 130 in the multiple first through holes 140a in a deposition manner.

Step 1500: Form a first connection portion on the first base portion. Further, in an embodiment shown in FIG. 5E, for example, the first connection portion 120 is formed on the first base portion 110 in a deposition manner.

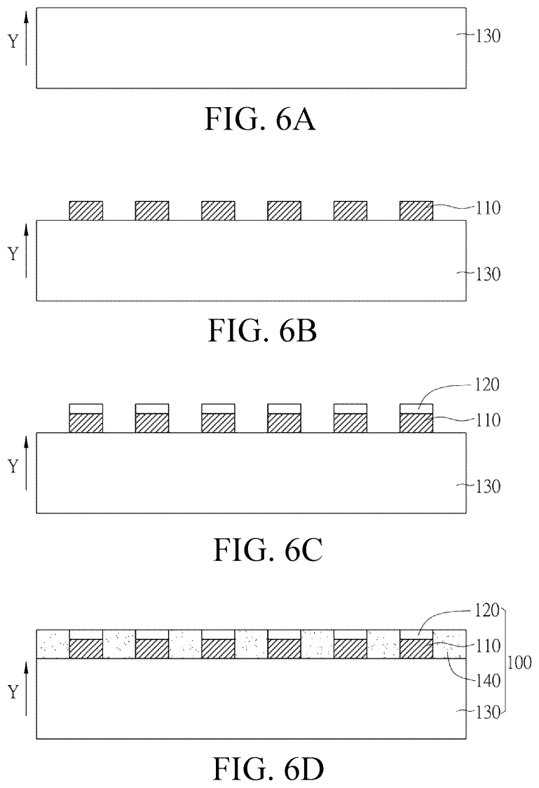

However, in a different embodiment, based on a design or manufacturing requirement, the first structure portion may be manufactured in different manners. After the first substrate 130 is provided in an embodiment of FIG. 6A, first, as shown in FIG. 6B, the first base portion 110 is disposed on a side of the first substrate 130, and then, as shown in FIG. 6C, the first connection portion 120 is formed on the first base portion 110, and as shown in FIG. 6D, the first isolation layer 140 is disposed on a side of the first substrate 130 to surround the first base portion 110 and the first connection portion 120. In addition, the second structure portion may be manufactured by using a same method or a different method as the first structure portion.

In an embodiment, Step 3000 includes: bringing the other side of the first connection portion with respect to the first base portion into contact with the other side of the second connection portion with respect to the second base portion; and activating the other side of the first connection portion with respect to the first base portion and the other side of the second connection portion with respect to the second base portion. More specifically, the step of activating the other side of the first connection portion with respect to the first base portion and the other side of the second connection portion with respect to the second base portion includes: increasing a temperature of the first structure portion and a temperature of the second structure portion. However, in a different embodiment, activation may be performed by increasing pressure.

The present invention has been described through the foregoing related embodiments. However, the foregoing embodiments are merely examples for implementing the present invention. It should be noted that the disclosed embodiments do not limit a scope of the present invention. On the contrary, modifications and equivalent arrangements included in the spirit and scope of this application are all included in the scope of the present invention.

### INDUSTRIAL APPLICABILITY

According to the bonding structure and the manufacturing method thereof in the present invention, defects or holes generated during bonding are reduced, thereby reducing manufacturing costs.

What is claimed is:

1. A bonding structure, comprising: a first structure portion and a second structure portion, wherein
the first structure portion comprises:
a first base portion; and
a first connection portion, disposed on a side of the first base portion, wherein the first base portion and the first connection portion have a same conductive material, and activity of the first connection portion is greater than activity of the first base portion; and
the second structure portion comprises:
a second base portion; and
a second connection portion, disposed on a side of the second base portion, wherein the second base portion and the second connection portion have a same conductive material, and activity of the second connection portion is greater than activity of the second base portion; and
the first structure portion and the second structure portion are connected to each other by docking the other side of the first connection portion with respect to the first base portion with the other side of the second connection portion with respect to the second base portion.

2. The bonding structure according to claim 1, wherein the first base portion and the second base portion are nano-twinned copper layers.

3. The bonding structure according to claim 1, wherein the first connection portion and the second connection portion have a self-annealing property.

4. The bonding structure according to claim 1, wherein the first connection portion and the second connection portion have a characteristic peak in a (111) direction.

5. The bonding structure according to claim 1, wherein no obvious interface is formed at a position at which the first connection portion and the second connection portion are docked.

6. The bonding structure according to claim 1, wherein the first base portion, the first connection portion, the second base portion, and the second connection portion are disposed along a Y axis, and the first connection portion and the second connection portion are aligned in a direction of the Y axis.

7. The bonding structure according to claim 1, wherein the first base portion, the first connection portion, the second base portion, and the second connection portion are disposed along a Y axis, and the first connection portion and the second connection portion are partially misaligned in a direction of the Y axis.

8. The bonding structure according to claim 1, wherein the first base portion, the first connection portion, the second base portion, and the second connection portion are disposed along a Y-axis direction, and an area of the second connection portion in a direction perpendicular to the Y axis is smaller than an area of the first connection portion in the direction perpendicular to the Y axis.

9. The bonding structure according to claim 1, wherein
the first structure portion further comprises:
a first substrate, wherein the first base portion is disposed on one side of the first substrate, and the first connection portion is located on the other side of the first base portion with respect to the first substrate; and
a first isolation layer, disposed on the same side of the first substrate as the first base portion, and surrounding the first base portion and the first connection portion; and
the second structure portion further comprises:
a second substrate, wherein the second base portion is disposed on one side of the second substrate, and the second connection portion is located on the other side of the second base portion with respect to the second substrate; and
a second isolation layer, disposed on the same side of the second substrate as the second base portion, and surrounding the second base portion and the second connection portion.

10. The bonding structure according to claim 9, wherein the first isolation layer and the second isolation layer are made of an insulating material.

11. A manufacturing method of a bonding structure, comprising:
providing a first structure portion, the first structure portion comprising:
a first substrate;
a first base portion, disposed on a side of the first substrate;
a first connection portion, disposed on the other side of the first base portion with respect to the first substrate, wherein the first base portion and the first connection portion have a same conductive material, and activity of the first connection portion is greater than activity of the first base portion; and
a first isolation layer, disposed on the same side of the first substrate as the first base portion, and surrounding the first base portion and the first connection portion;
providing a second structural portion, the second structure portion comprising:
a second substrate;
a second base portion, disposed on a side of the second substrate;
a second connection portion, disposed on a side of the second base portion, wherein the second base portion and the second connection portion have a same conductive material, and activity of the second connection portion is greater than activity of the second base portion; and
a second isolation layer, disposed on the same side of the second substrate as the second base portion, and surrounding the second base portion and the second connection portion; and
docking the other side of the first connection portion with respect to the first base portion with the other side of the second connection portion with respect to the second base portion to connect the first structure portion and the second structure portion.

12. The manufacturing method of a bonding structure according to claim 11, wherein the step of providing a first structure portion comprises:
providing the first substrate;
disposing the first isolation layer on a side of the first substrate;
forming multiple first through holes in the first isolation layer;
forming the first base portion on the first substrate in the multiple first through holes; and
forming the first connection portion on the first base portion.

13. The manufacturing method of a bonding structure according to claim 11, wherein the step of docking the other side of the first connection portion with respect to the first base portion with the other side of the second connection portion with respect to the second base portion comprises:
bringing the other side of the first connection portion with respect to the first base portion into contact with the other side of the second connection portion with respect to the second base portion; and
activating the other side of the first connection portion with respect to the first base portion and the other side of the second connection portion with respect to the second base portion.

14. The manufacturing method of a bonding structure according to claim 13, wherein the first base portion, the first connection portion, the second base portion, and the second connection portion are disposed along a Y axis, wherein the step of bringing the other side of the first connection portion with respect to the first base portion into contact with the other side of the second connection portion with respect to the second base portion comprises: aligning the first connection portion and the second connection portion in a direction of the Y axis.

15. The manufacturing method of a bonding structure according to claim 13, wherein the first base portion, the first connection portion, the second base portion, and the second connection portion are disposed along a Y axis, wherein the step of bringing the other side of the first connection portion with respect to the first base portion into contact with the other side of the second connection portion with respect to the second base portion comprises: partially misaligning the first connection portion and the second connection portion in a direction of the Y axis.

16. The manufacturing method of a bonding structure according to claim 13, wherein the step of activating the other side of the first connection portion with respect to the first base portion and the other side of the second connection portion with respect to the second base portion comprises: increasing a temperature of the first structure portion and a temperature of the second structure portion.

17. The manufacturing method of a bonding structure according to claim 11, wherein the first base portion and the second base portion are made of nano-twinned copper.

18. The manufacturing method of a bonding structure according to claim 11, wherein the first connection portion and the second connection portion have a self-annealing property.

19. The manufacturing method of a bonding structure according to claim 11, wherein the first connection portion and the second connection portion have a characteristic peak in a (111) direction.

20. The manufacturing method of a bonding structure according to claim 11, wherein the first isolation layer and the second isolation layer are made of an insulating material.
